(19) United States
(12) Patent Application Publication
(10) Pub. No.: US 2007/0196971 A1
(43) Pub. Date: Aug. 23, 2007

(54) Scalable embedded EEPROM memory cell

(76) Inventor: Bohumil Lojek, Colorado Springs, CO (US)

Correspondence Address: SCHNECK & SCHNECK, P.O. BOX 2-E, SAN JOSE, CA, 95109-0005, US

(21) Appl. No.: 11/359,284

(22) Filed: Feb. 22, 2006

(51) Int. Cl. H01L 21/8234

(52) U.S. Cl. 438/197

(57) ABSTRACT

The present invention includes a method and a resultant device that have components that may be formed below a limit of resolution of optical lithography by utilizing spacers to separate laterally displaced features (i.e., features that have spatial dimensions less than the limit of resolution in planes parallel to a face of a substrate or wafer, or x-y dimensions). The present invention also prevents gates or other conductive lines from coupling into each other by varying a height of each of the gates or conductive lines from each other (i.e., dimensions normal to the face of the substrate or wafers, or various z-heights).

### TECHNICAL FIELD

The invention relates generally to a process for fabricating an integrated circuit structure, and more specifically to a process for producing EEPROM memory cells below a resolution limit of photolithography.

### BACKGROUND ART

There is a need in the integrated circuit art for obtaining increasingly smaller devices without sacrificing device performance. The small device size requires small device regions, precise and accurate alignment between regions, and minimization of parasitic resistances and capacitances. Device size can be reduced by putting more reliance on fine line lithography, but as discussed below, it becomes impractical or impossible to continue to reduce feature size and achieve the required greater increase in alignment accuracy. As lithography is pushed to its limit, yield and production throughput decrease.

Four governing performance parameters of an optical photolithographic system are limit-of-resolution, Lᵣ, level-to-level alignment accuracy, depth-of-focus, and throughput. For purposes of this discussion, limit-of-resolution, level-to-level alignment, and depth-of-focus are physically constrained parameters.

Typical photolithographic techniques are limited by physical constraints of the photolithographic system involving actinic radiation wavelength, λ, and geometrical configurations of the projection system optics. According to Rayleigh's criterion,

$${L}_{r} = \frac{0.61 λ}{NA}$$

where NA is the numerical aperture of the optical system and is defined as NA=n sin α, where n is the index of refraction of the medium which the radiation traverses (usually air for this application, so n≅1) and α is a half-angle of divergence of the actinic radiation. For example, using deep ultraviolet (DUV) illumination with λ=193 nm, and NA=0.7, the lower limit of resolution is 168 nanometers (1680 Å). Techniques such as phase-shifted masks can extend this limit downward, but photomasks required employing this technique are extremely expensive. This expense becomes greatly compounded with a realization that an advanced semiconductor process may employ more than 25 photomasks.

Along with the limit-of-resolution, the second parameter, level-to-level alignment accuracy, becomes more critical as feature sizes on photomasks decrease and a number of total photomasks increases. For example, in a worst case scenario if photomask alignment by itself causes a reduction in device yield to 95% per layer, then 25 layers of photomask translates to a total device yield of 0.95²⁵=0.28 or 28% yield (assuming statistically-independent errors). Therefore, a more complicated mask, such a phase-shifted mask is not only more expensive but device yield can suffer dramatically.

Further, although the numerical aperture of the photolithographic system may be increased to lower the limit-of-resolution, the third parameter, depth-of-focus, will suffer as a result. Depth-of-focus is inversely proportional to NA². Therefore, as NA increases, limit-of-resolution decreases but depth-of-focus decreases more rapidly. The reduced depth-of-focus makes accurate focusing more difficult especially on non-planar features such as “Manhattan Geometries” becoming increasingly popular in advanced semiconductor devices.

Consequently, there are at least two challenges in fabricating scalable ultra-small EEPROM memory devices currently: (1) each component of an EEPROM memory device (i.e., components of a select transistor and a memory transistor) must have dimensions smaller than a limit of optical photolithography allows and additionally be located in close proximity to each other; and (2) dimensions or placement of either a floating gate or a control gate of the memory transistor cannot couple into a gate of the select transistor (or vice versa). Thus, reduced sizes of EEPROM memory cells must depend upon scalability in all three spatial dimensions.

### SUMMARY

Embodiments of the present invention include a method and a resultant device that have components that may be formed below a limit of resolution of optical photolithography by utilizing spacers to separate laterally displaced features (i.e., features that have spatial dimensions less than the limit of resolution in planes parallel to a face of a substrate or wafer, or x-y dimensions). The present invention also prevents gates or other conductive lines from coupling into each other by varying a height of each of the gates or conductive lines from each other (i.e., by varying dimensions normal to the face of the substrate or wafers, or various z-heights).

In one exemplary embodiment, a method of fabricating an electronic integrated circuit device includes forming a first dielectric film on a substrate; forming a window (e.g., an oxide tunneling window) in the first dielectric film by etching the first dielectric film; and forming a first dopant region through the window. A first pedestal, forming a basis for a memory transistor of a memory cell, is formed over the window region. The first pedestal is formed of a semiconducting material (e.g., polysilicon) and has a first height. The first pedestal is then surrounded, along with any exposed portions of the first dielectric film, with a second dielectric film. A first spacer is formed that substantially surrounds both the first pedestal and an outer periphery of a portion of the second dielectric film that surrounds the first pedestal. The first spacer is comprised of a material dissimilar to the second dielectric film such that a selective etchant may be used to etch other film layer or layers without affecting an integrity of the spacers. A “width” of the spacers is dependent upon both a thickness of the deposited spacer layer and a step-height over which the deposited spacer layer is deposited. Etching of the spacer layer is performed such that substantially all horizontal surfaces (i.e., those parallel to the face of the substrate) are etched while leaving vertical surfaces substantially intact. Such etches are accomplished by, for example, a reactive ion etch (RIE). Thus, the width of the spacers and any underlying features are conceivably less than or equal to the thickness of the spacer film layer itself (e.g., as thin as approximately 30 Å or less). A second semiconducting film comprised of a second semiconducting material is then formed over the second dielectric film, followed by depositing a third dielectric film over the second semiconducting film. An etch of the third dielectric film is performed to form a second pedestal region. A second spacer is then formed to substantially surround a periphery of the second pedestal region formed by the third dielectric film. The second spacer is comprised of a material dissimilar to either the first dielectric film or to the second semiconducting film to allow an advantageous use of selective etchants. The second spacer is then used to etch the underlying second semiconducting film thus forming a second pedestal; the second pedestal thus forms a basis for a select transistor of the memory cell and is comprised of a second semiconducting material and having a second height. The second height is less than the first height thus advantageously using overall height differences in topology to avoid coupling of any gates or other conductive lines. A second dopant region is formed in the first surface of the substrate between the first pedestal and the second pedestal followed by contemporary fabrication steps to complete the memory cell device.

Another embodiment of the present invention is an EEPROM memory cell fabricated using a fabrication process described herein. The memory cell, in one exemplary embodiment, includes a memory transistor having a floating gate with a first height. The floating gate is comprised substantially of a first semiconducting material and is constructed over a substrate with a gate dielectric material located between the floating gate and the substrate. A second dielectric material is formed over an uppermost portion of the floating gate and a memory transistor control gate is disposed substantially over both the floating gate and the gate dielectric material. A select transistor is located laterally proximal to and in electrical communication with the memory transistor. The select transistor includes a select gate being substantially comprised of a second semiconducting material and having a second height. The second height is less than the first height. The select transistor also shares a dopant region with the memory transistor where the dopant region is located between the select gate and a proximal end of the memory transistor control gate. A distance between the select gate and the proximal end of the memory transistor control gate is generated using spacers and is thus less than a limit of resolution of optical photolithography.

### BRIEF DESCRIPTION OF THE DRAWINGS

FIGS. 1A-1O show cross-sections of an EEPROM memory cell during various exemplary fabrication stages.

### DETAILED DESCRIPTION

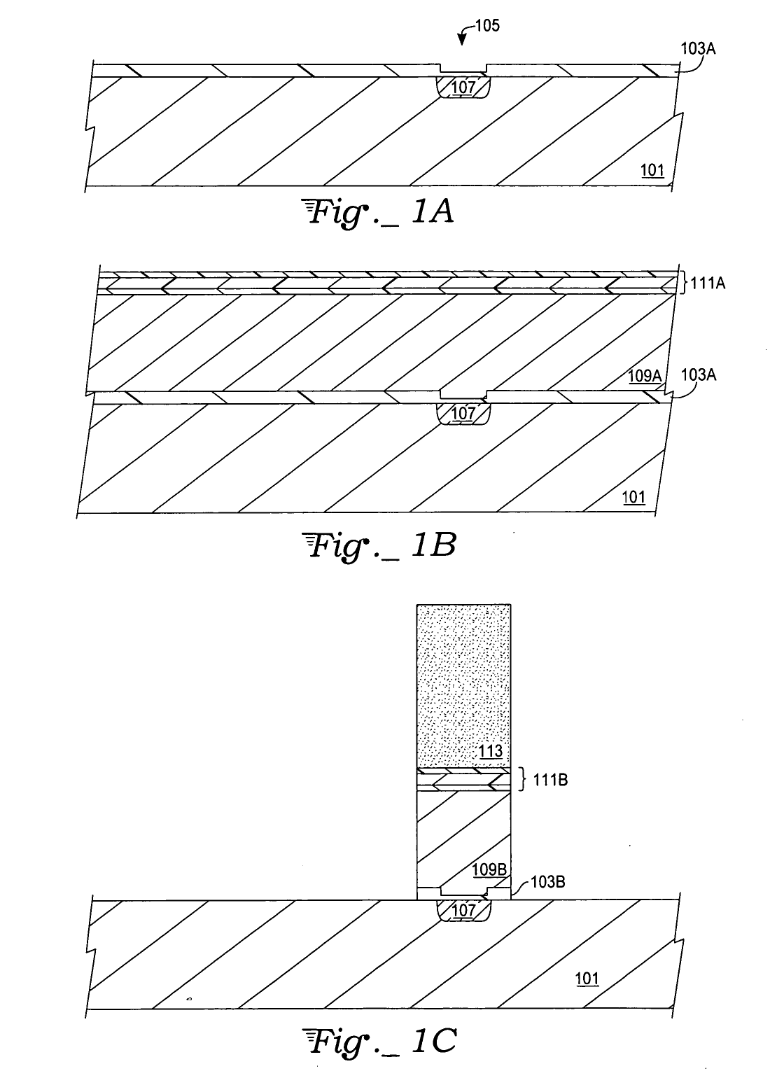

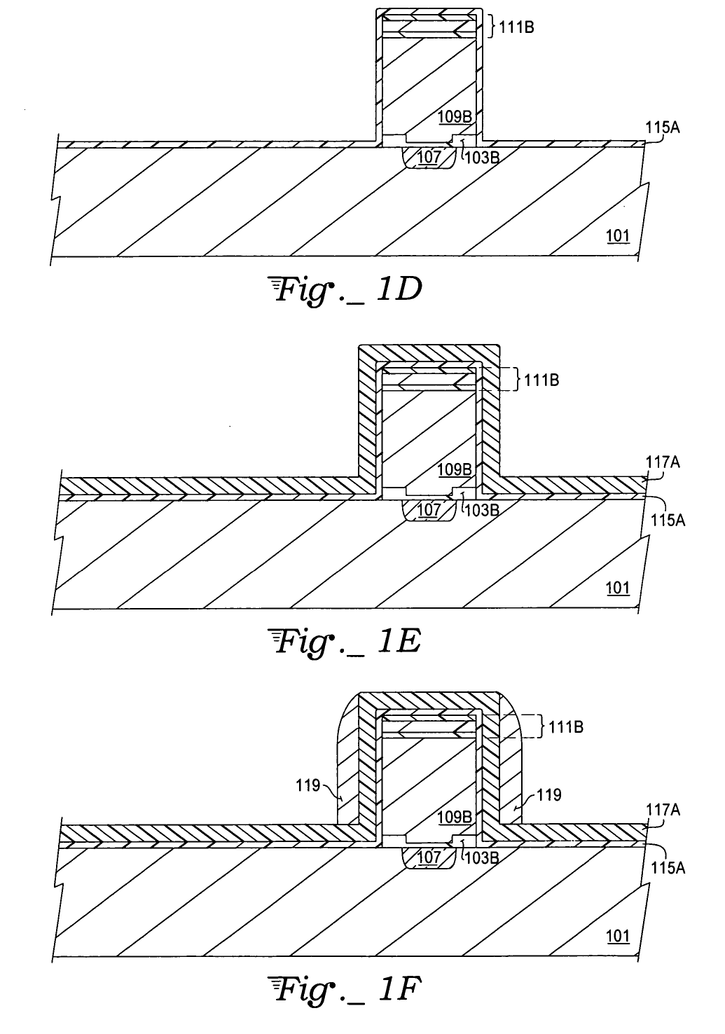

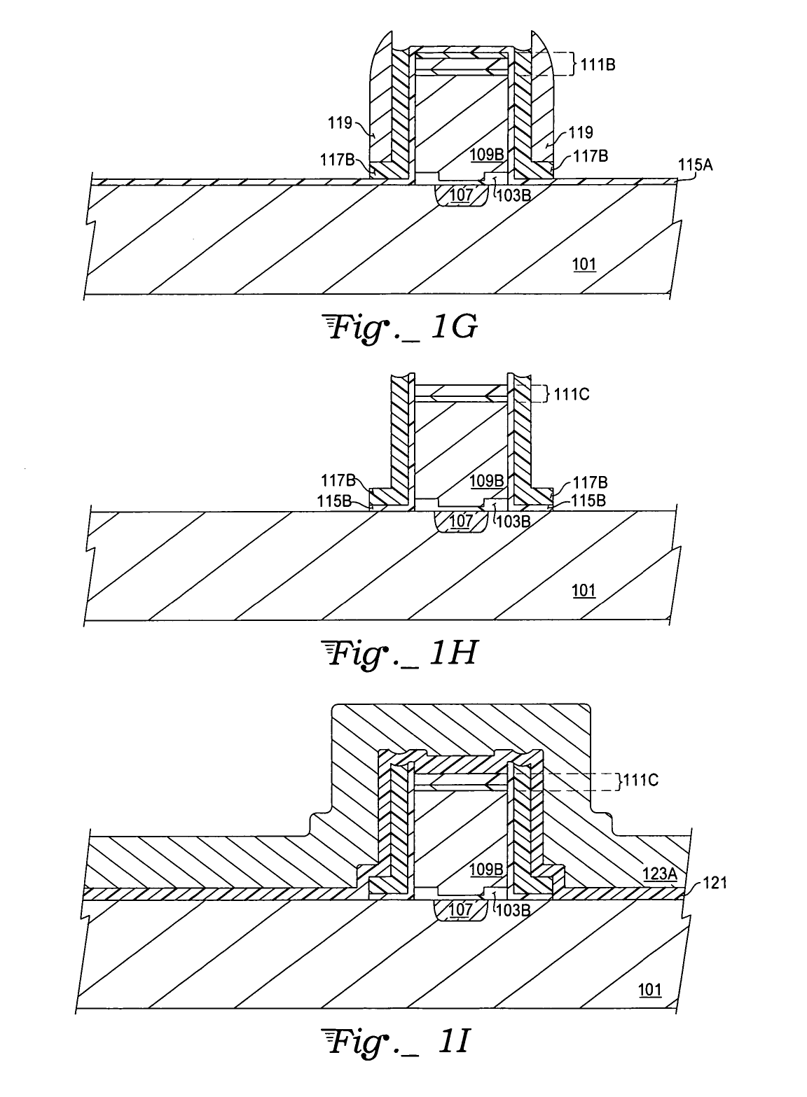

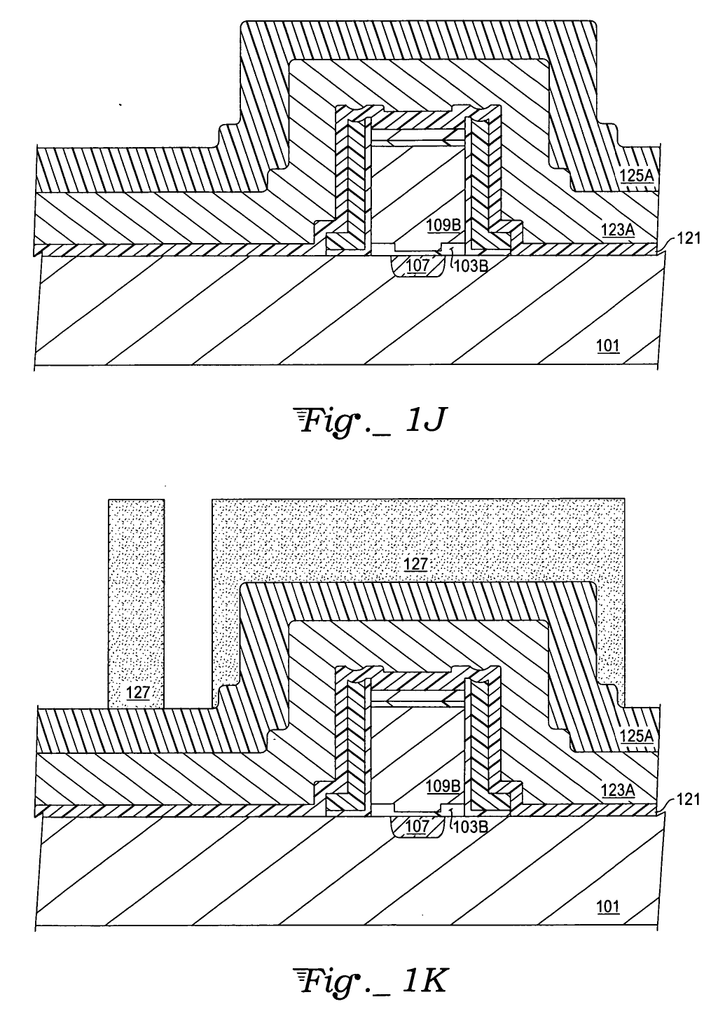

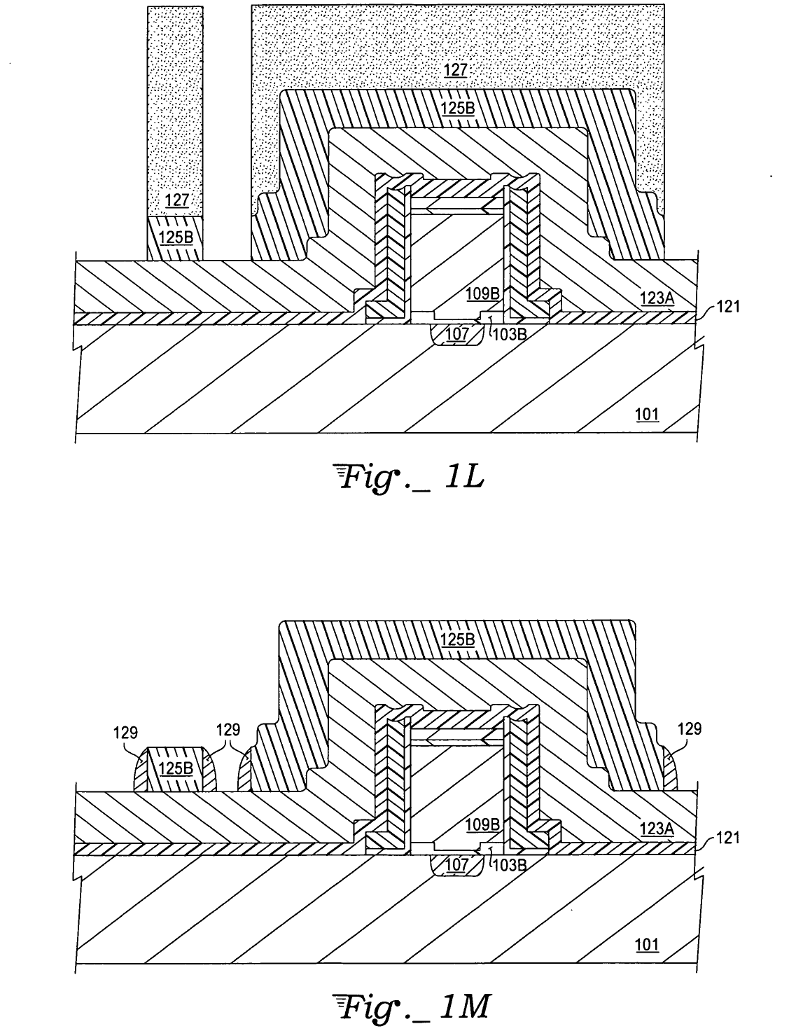

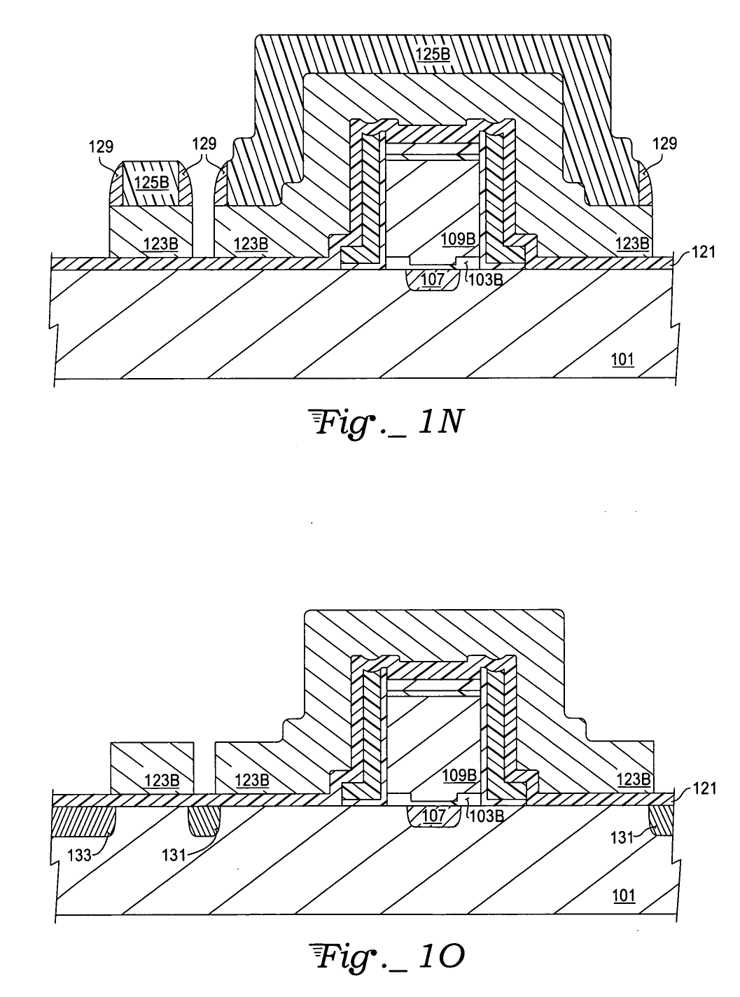

With reference to FIG. 1A, a cross-section of a substrate 101 includes a first oxide layer 103A. The first oxide layer 103A is partially etched through in a small region to form an oxide window 105. (Note that the oxide window may also be fully etched through, followed by a brief reoxidation period to regrow a thin silicon dioxide film within the oxide window 105 if silicon is chosen for the substrate 101.) The oxide window 105 is formed by techniques known to one of skill in the art. Below the oxide window 105, a first drain region 107 is formed by diffusing or implanting a semiconductor dopant through the oxide window 105.

In a specific exemplary embodiment, the substrate 101 is a p-type silicon wafer or p-type well. The first oxide layer 103A is approximately 200 Å thick with the oxide window etched to be approximately 40 Å-70 Å thick. The first oxide layer 103A may be formed by a thermal oxidation technique. Alternatively, the first oxide layer 103A may be deposited by any of a variety of techniques such as chemical vapor deposition (CVD), low-pressure CVD (LPCVD), plasma-enhanced CVD (PECVD), or plasma-assisted CVD (PACVD).

In FIG. 1B, a first polysilicon layer 109A is formed over the first oxide layer 103A. An oxide-nitride-oxide (ONO) layer 111A is then formed over the first polysilicon layer 109A. A blanket layer of photoresist (not shown) is formed over the ONO layer 111A. The layer of photoresist is then exposed (e.g., photolithographically patterned), developed, and etched to form an etched first photoresist mask 113 (FIG. 1C). In a specific exemplary embodiment, the ONO layer 111A is formed to be approximately 80 Å thick while the first polysilicon layer 109A is formed to be about 1000 Å to 1500 Å thick.

Layers underlying the etched first photoresist mask 113 are etched with various techniques and/or chemistries to form an etched ONO layer 111B, an etched first polysilicon layer 109B (thus forming a polysilicon pedestal), and an etched first oxide layer 103B. Etching of listed underlying layers can occur through various wet-etch techniques (e.g., the first oxide layer 103A may be etched in hydrofluoric acid, such as contained in a standard buffered oxide etch (BOE), or orthophosphoric acid) or dry etch techniques (e.g., reactive-ion-etching (RIE)). Such etching techniques are known in the semiconductor art.

The etched first photoresist mask 113 is stripped and a first blanket conformal oxide layer 115A is deposited (FIG. 1D) to a thickness of, for example, 80 Å to 200 Å. A pronounced vertical structure of FIG. 1D including the etched first oxide layer 103B, the etched first polysilicon layer 109B, and portions of the ONO layer 111B and the blanket conformal oxide layer 115A form a basic structure for a floating gate memory cell, described in more detail, infra. A blanket nitride layer 117A is then deposited (FIG. 1E) over the conformal oxide layer 115A. The blanket nitride layer 117A may be deposited, in a specific exemplary embodiment, to a thickness of 500 Å to 1500 Å. A second blanket oxide layer (not shown) is deposited, patterned, and etched to create an oxide spacer 119. The etching is typically performed using an RIE process, thus removing primarily those portions of the second blanket oxide layer that are substantially parallel (i.e., horizontal portions) to an uppermost surface of the substrate 101. The RIE process thus leaves substantially intact vertical portions of the second blanket oxide layer. Therefore, the oxide spacer 119 is self-aligned with a given feature. Further, the spacer allows an etch or alignment step surrounding the given feature to be below a photolithographic limit of resolution since the etch or alignment is now based merely on a thickness of the second blanket oxide layer and a step-height of a proximate structure. Additionally, other semiconductors or dielectric materials may be used to from a spacer or spacers. Since the size of the spacer is dependent on the thickness of chosen film layers, spacers may be created as thin as approximately 30 Å or less. Here, a thickness of the oxide spacer 119 is chosen to etch back portions of the blanket conformal oxide layer 115A and the nitride layer 117A which are not underlying the oxide spacer 119. For film thicknesses listed in the specific exemplary embodiments given herein, the oxide spacer 119 is approximately 1000 Å.

In FIG. 1G, a highly selective reactive ion etch is chosen to etch the blanket nitride layer 117A thus creating the etched nitride layer 117B. A skilled artisan will recognize that various chemistries may be chosen which will readily etch, for example, an oxide layer while leaving a nitride layer essentially intact (or vice versa) or, in other embodiments, etch a nitride layer while leaving a silicon dioxide layer intact. Therefore, etches of one layer may be performed while leaving adjacent layers intact, thus avoiding tedious and critical timing steps. Layers comprised of materials dissimilar to the layer being etched thus serve as an etch stop.

With reference to FIG. 1H, a selective etch is used to remove the oxide spacer 119 and form an etched conformal oxide layer 115B. (Note that, depending on etch chemistry used, either the oxide spacer 119 or the conformal oxide layer 115A may be etched prior to the other. In either case, the etched nitride lay 117B serves as an etch mask for the conformal oxide layer 115A.) Also, notice an uppermost oxide layer of the ONO layer 111B has also been etched away, leaving an oxide-nitride layer 111C.

In FIG. 1I, a second oxide layer 121 followed by a second polysilicon layer 123A have been deposited. The second polysilicon layer 123A will form one of the electrodes for the floating gate memory cell, described in more detail, infra. A third oxide layer 125A is then conformally deposited (FIG. 1J). A second layer of photoresist (not shown) is formed over the third oxide layer 125A. The layer of photoresist is then exposed (e.g., photolithographically patterned), developed, and etched to form an etched second photoresist mask 127 (FIG. 1K). In a specific exemplary embodiment, the second oxide layer 121 is formed to be approximately 50 Å to 80 Å in thickness. The second polysilicon layer 123A is about 1500 Å thick while the third oxide layer 125A is approximately 1000 Å to 2000 Å thick.

The etched second photoresist mask 127 serves as an etch mask to etch the third oxide layer 125A. Once the third oxide layer 125A is etched, an etched third oxide layer 125B is produced (FIG. 1L). The etched third oxide layer 125B is produced using a selective etchant such that the underlying second polysilicon layer 123A serves as an etch stop.

With reference to FIG. 1M, the etched second photoresist mask 127 is removed. A conformal blanket layer of nitride (not shown) is deposited, followed by a predominantly vertical etch (e.g., RIE) producing nitride spacers 129 on vertical sidewalls of the etched third oxide layer 125B. The nitride spacers 129, in one embodiment, are approximately 500 Å to 1000 Å thick and serve to produce a fine-resolution etch mask for the underlying second polysilicon layer 123A. The nitride spacers 129 are thus used to produce an etched second polysilicon layer 123B (FIG. 1N). Using dissimilar materials for spacers, etch masks, and etch stops simplifies an entire fabrication process flow by eliminating etch-time as a predominant factor and relying instead on etch selectivity. Thus, difficult to control time-critical etch steps are eliminated.

In FIG. 1O, source regions 131 and a second drain region 133 are formed by diffusing or implanting a semiconductor dopant through the second oxide layer 121 where portions of the etched second polysilicon layer 123B have been etched through. An isolated portion of the etched second polysilicon layer 123B (the pedestal on the left side of FIG. 1O, located between the second drain region 133 and one of the source regions 131) will serve as a gate for the select transistor. The etched first polysilicon layer 109B serves as a floating gate for the memory transistor while the remaining portion of the etched polysilicon layer 123B (i.e., that portion surrounding the floating gate) will form the control gate of the memory transistor. Thus, FIG. 1O represents a nearly completed EEPROM memory cell fabricated in accordance with an exemplary embodiment of the present invention.

Considering an uppermost surface of the substrate to lie in an x-y plane and a thickness of various film layers (i.e., a “height” of fabricated features to lie in a z-direction, one can see that any device fabricated in accordance with the present invention benefits from scaling capabilities in all three spatial dimensions. At least three criteria should be considered. First, minimal lateral feature sizes with design rules less than the photolithographic limit may be accomplished in various x-y planar levels through a use of spacers. Thus, utilization of design rules far smaller than may be achieved through conventional lithography may be accomplished by fabricating spacers (for example, using a variety of materials such as oxide, nitride, or polysilicon) to define device geometries on underlying semiconducting layers. Lateral device geometries then relate to a thickness, rather than a width, of a deposited dielectric layer. Second, a use of dissimilar materials on adjacent layers and/or between main layers and spacers eliminate critical timing issues and may be adjusted through a judicious use of various selective chemistries. Thirdly, differing z-heights, especially for polysilicon or electrode connection levels minimize or alleviate potential electrical shorting or other deleterious effects (e.g., such as parasitic coupling) which occur more readily when such features are at a uniform height.

In the foregoing specification, the present invention has been described with reference to specific embodiments thereof. It will, however, be evident to a skilled artisan that various modifications and changes can be made thereto without departing from the broader spirit and scope of the invention as set forth in the appended claims. For example, skilled artisans will appreciate that other types of semiconducting and insulating materials other than those listed may be employed. Additional particular process fabrication and deposition techniques, such as low pressure chemical vapor deposition (LPCVD), ultra-high vacuum CVD (UHCVD), and low pressure tetra-ethoxysilane (LPTEOS) may be readily employed for various layers and still be within the scope of the present invention. Although the exemplary embodiments describe particular types of dielectric and semiconductor materials, one skilled in the art will realize that other types of materials and arrangements of materials may also be effectively utilized and achieve the same or similar advantages. Also, the substrate itself may be comprised of a non-semiconducting material, for example, a quartz reticle with a deposited and doped polysilicon layer followed by an anneal step (e.g., rapid-thermal annealing (RTA) or an excimer laser annealing (ELA)). Additionally, although the exemplary embodiments are described in terms of an EEPROM memory cell integrated circuit device, a person of ordinary skill in the art will recognize that other integrated circuit devices may readily benefit from the fabrication process described herein as well. The specification and drawings are, accordingly, to be regarded in an illustrative rather than a restrictive sense.

What is claimed is:

1. A method of fabricating an electronic integrated circuit device, comprising:
providing a substrate, the substrate having a first surface;
forming a first dielectric film on the first surface of the substrate;
forming a window in the first dielectric film by etching the first dielectric film;
forming a first dopant region through the window in the first dielectric film and into the first surface of the substrate;
forming a first pedestal over the window formed in the first dielectric film, the first pedestal being comprised of a first semiconducting material and having a first height;
surrounding the first pedestal and any exposed portions of the first dielectric film with a second dielectric film;
forming a first spacer to substantially surround both the first pedestal and an outer periphery of a portion of the second dielectric film that surrounds the first pedestal, the first spacer being comprised of a material dissimilar to the second dielectric film;
forming a second pedestal over the second dielectric film and in lateral proximity to the first pedestal, the second pedestal being comprised of a second semiconducting material and having a second height, the second height being less than the first height; and
forming a second dopant region in the first surface of the substrate between the first pedestal and the second pedestal.

2. The method of claim 1 wherein the step of forming a second pedestal comprises:
depositing a second semiconducting film comprised of the second semiconducting material over the second dielectric film;
depositing a third dielectric film over the second semiconducting film;
etching the third dielectric film thus forming a second pedestal region;
forming a second spacer substantially surrounding a periphery of the second pedestal region formed by the third dielectric film, the second spacer being comprised of a material dissimilar to either the first dielectric film or to the second semiconducting film; and
using the second spacer to etch the second semiconducting film thus forming the second pedestal.

3. The method of claim 2 wherein a thickness of the second spacer is less than a limit of resolution of optical photolithography.

4. The method of claim 1 further comprising forming a third dopant region on a side of the second pedestal distal to the first pedestal.

5. The method of claim 1 wherein the window is formed by partially etching into the first dielectric film.

6. The method of claim 1 wherein the window is formed by etching through the first dielectric film.

7. The method of claim 1 wherein the first semiconducting material and the second semiconducting material substantially comprise the same type of material.

8. The method of claim 1 wherein the first semiconducting material and the second semiconducting material are substantially comprised of polysilicon.

9. The method of claim 1 wherein a thickness of the first spacer is less than a limit of resolution of optical photolithography.

10. A method of fabricating an electronic integrated circuit device, comprising:
providing a substrate, the substrate having a first surface;
forming a first dielectric film on the first surface of the substrate;
forming a window in the first dielectric film by etching the first dielectric film;
forming a first dopant region through the window in the first dielectric film and into the first surface of the substrate;
forming a first pedestal over the window formed in the first dielectric film, the first pedestal forming a basis for a memory transistor of a memory cell and being comprised of a first semiconducting material and having a first height;
surrounding the first pedestal and any exposed portions of the first dielectric film with a second dielectric film;
forming a first spacer to substantially surround both the first pedestal and an outer periphery of a portion of the second dielectric film that surrounds the first pedestal, the first spacer being comprised of a material dissimilar to the second dielectric film;
depositing a second semiconducting film comprised of a second semiconducting material over the second dielectric film;
depositing a third dielectric film over the second semiconducting film;
etching the third dielectric film thus forming a second pedestal region;
forming a second spacer substantially surrounding a periphery of the second pedestal region formed by the third dielectric film, the second spacer being comprised of a material dissimilar to either the first dielectric film or to the second semiconducting film;
using the second spacer to etch the second semiconducting film thus forming a second pedestal, the second pedestal forming a basis for a select transistor of the memory cell and being comprised of a second semiconducting material and having a second height, the second height being less than the first height; and
forming a second dopant region in the first surface of the substrate between the first pedestal and the second pedestal.

11. The method of claim 10 wherein a thickness of the second spacer and the third spacer are each less than a limit of resolution of optical photolithography.

12. The method of claim 10 further comprising forming a third dopant region on a side of the second pedestal distal to the first pedestal.

13. The method of claim 10 wherein the window is formed by partially etching into the first dielectric film.

14. The method of claim 10 wherein the window is formed by etching through the first dielectric film followed by a thermal reoxidation step.

15. The method of claim 10 wherein the first semiconducting material and the second semiconducting material are substantially comprised of polysilicon.

16. An EEPROM memory cell, comprising:
a memory transistor including
(i) a floating gate having a first height, the floating gate being comprised substantially of a first semiconducting material and being constructed over a substrate;
(ii) a gate dielectric material located between the floating gate and the substrate;
(iii) a second dielectric material formed over an uppermost portion of the floating gate; and
(ii) a memory transistor control gate disposed substantially over both the floating gate and the gate dielectric material; and
a select transistor located laterally proximal to and in electrical communication with the memory transistor, the select transistor including:
(i) a select gate being comprised substantially of a second semiconducting material and having a second height, the second height being less than the first height; and
(ii) a dopant region shared with the memory transistor, the dopant region being located between the select gate and a proximal end of the memory transistor control gate, a distance between the select gate and the proximal end of the memory transistor control gate being less than a limit of resolution of optical photolithography.

17. The EEPROM memory cell of claim 16 wherein the shared dopant region is doped to act as a source region.

18. The EEPROM memory cell of claim 16 wherein the gate dielectric material is silicon dioxide.

19. The EEPROM memory cell of claim 16 wherein the substrate is a silicon wafer.

20. The EEPROM memory cell of claim 16 wherein the first semiconducting material and the second semiconducting material are each comprised substantially of polysilicon.

21. A method of fabricating an electronic integrated circuit device, comprising:
forming a first dielectric film on a first surface of a substrate;
forming a first pedestal over the window formed in the first dielectric film, the first pedestal being comprised of a first semiconducting material and having a first height;
surrounding the first pedestal and any exposed portions of the first dielectric film with a second dielectric film;
forming a second pedestal over the second dielectric film and in lateral proximity to the first pedestal, the second pedestal being comprised of a second semiconducting material and having a second height, the second height being less than the first height; and
forming a dopant region in the first surface of the substrate between the first pedestal and the second pedestal.

22. The method of claim 1, further comprising controlling a distance between the first pedestal and the second pedestal with at least one fabricated spacer, a thickness of the fabricated spacer being formed to be less than a limit of resolution of optical photolithography.
